(19) United States
(12) Patent Application Publication
(10) Pub. No.: US 2023/0027751 A1
(43) Pub. Date: Jan. 26, 2023

(54) LIGHT EMITTING DEVICE

(71) Applicant: SHARP KABUSHIKI KAISHA, Sakai City, Osaka (JP)

(72) Inventor: YOSHIHIRO UETA, Sakai City, Osaka (JP)

(21) Appl. No.: 17/788,095

(22) PCT Filed: Jan. 16, 2020
(86) PCT No.: PCT/JP2020/001248

§ 371 Date: Jun. 22, 2022

(51) Int. Cl. H01L 27/32; H01L 51/52; H01L 51/56

(52) U.S. Cl. CPC H01L 27/3262; H01L 51/5271; H01L 51/56; H01L 2227/323; H01L 27/1225

(57) ABSTRACT

The light-emitting device includes a thin film transistor having a channel layer made of a first n-type semiconductor; a cathode electrically connected to a drain of the thin film transistor and made of a second n-type semiconductor; an anode facing the cathode; and a light-emitting layer provided between the cathode and the anode.

### TECHNICAL FIELD

The present invention relates to a light-emitting device.

### BACKGROUND ART

For example, PTL 1 discloses an organic electroluminescence element in which a cathode, an organic light-emitting layer, an inorganic thin film layer, and an anode are layered.

### CITATION LIST

### Patent Literature

PTL 1: JP 2000-235893 A

### SUMMARY OF INVENTION

### Technical Problem

In order to drive the organic light emitting diode (light-emitting portion) described in Cited Document 1, for example, a switching element such as a thin film transistor (TFT) is used. That is, it can be said that a combination of the light-emitting portion and the TFT functions as one light emitting diode. Further, as a method for connecting the TFT and the light-emitting portion, for example, it is conceivable to layer and connect them. However, depending on the combination of the type of TFT, the configuration of the light-emitting portion, the layering order of the TFT and the light-emitting portion, and the like, the drive voltage of the light emitting diode is increased, whereby a good luminous efficiency may not be achieved. In view of this, one aspect of the present invention is directed to providing a light emitting diode that achieves a good luminous efficiency.

### Solution to Problem

A light-emitting device according to one aspect of the present invention is a light-emitting device including a thin film transistor having a channel layer made of a first n-type semiconductor; a cathode electrically connected to a drain of the thin film transistor and made of a second n-type semiconductor; an anode facing the cathode; and a light-emitting layer provided between the cathode and the anode.

### Advantageous Effects of Invention

The one aspect of the present invention can provide a light-emitting device that achieves a good luminous efficiency.

### BRIEF DESCRIPTION OF DRAWINGS

FIG. 1 is a cross-sectional view schematically illustrating an example of a layered structure of a light-emitting device according to a first embodiment.

FIG. 2 is a table showing an example of characteristics of an n-type semiconductor material.

FIG. 3 is a flowchart illustrating a process for manufacturing a light-emitting device according to the first embodiment.

FIG. 4 is a cross-sectional view schematically illustrating an example of a layered structure of a light-emitting device according to a second embodiment.

### DESCRIPTION OF EMBODIMENTS

### First Embodiment

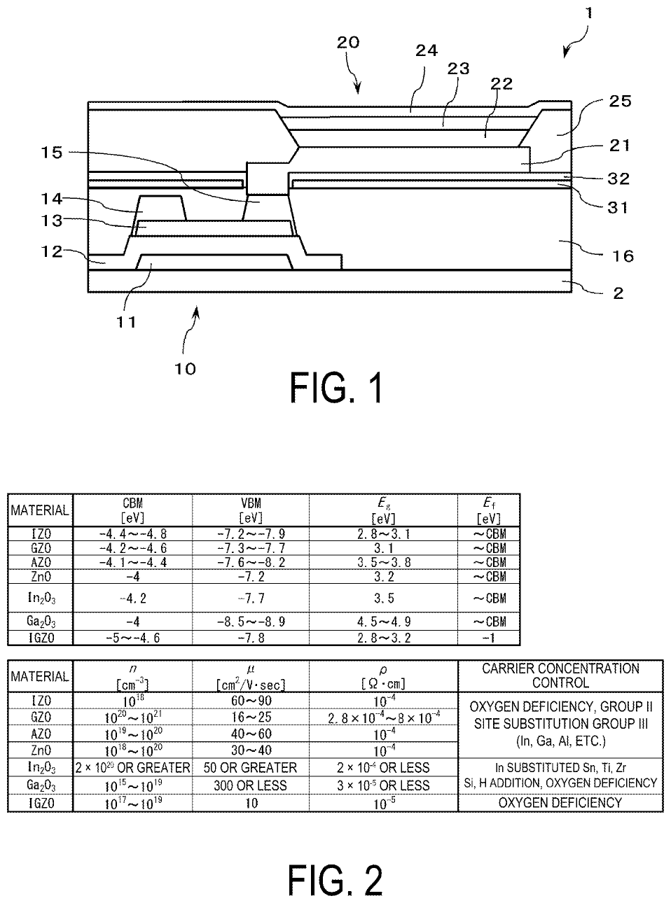

Hereinafter, an embodiment of the disclosure will be described. FIG. 1 is a cross-sectional view schematically illustrating an example of a layered structure of a light-emitting device 1 according to the present embodiment.

As illustrated in FIG. 1, the light-emitting device 1 includes, for example, a thin film transistor (TFT) 10 provided on a substrate 2 and a light-emitting portion 20. The light-emitting portion 20 is controlled by the TFT 10, which is a switching element, and emits light. Although one pixel is illustrated in FIG. 1, for example, a plurality of the pixels are arranged and formed, so that a display device can be made.

The TFT 10 includes a gate electrode 11, a gate insulating layer 12, a channel layer 13, a source electrode 14, and a drain electrode 15, for example.

The gate electrode II is formed on the substrate 2. An insulating layer may be provided between the substrate 2 and the gate electrode 11. The gate electrode 11 is formed of a metal material such as copper or titanium, for example.

The gate insulating layer 12 is formed on the gate electrode 11. The gate insulating layer 12 insulates the gate electrode 11. The gate insulating layer 12 is formed of a transparent insulating material such as silicon nitride or silicon oxide, for example.

The channel layer 13 is formed on the gate electrode 11 and the gate insulating layer 12. The TFT 10 in the present embodiment is a so-called n-channel type TFT. Thus, the channel layer 13 is made of an n-type semiconductor (hereinafter, the n-type semiconductor in the channel layer 13 is sometimes referred to as a second n-type semiconductor). Examples of a material that may serve as this n-type semiconductor include indium gallium zinc oxide (IGZO), indium zinc oxide (IZO), gallium-added zinc oxide (GZO), aluminum-added zinc oxide (AZO), ZnO, In₂O₃, Ga₂O₃, and the like. Further, in the channel layer 13, a portion connected to the source electrode 14 and a portion connected to the drain electrode 15 each are, for example, doped with an impurity to be a p-type semiconductor.

The source electrode 14 and the drain electrode 15 are formed on the channel layer 13, and are connected to the channel layer 13. The source electrode 14 and the drain electrode 15 are formed of a metal material such as copper or titanium, f©r example.

A flattening layer 16, a reflective layer 31, and a reflective layer insulating layer 32 are layered in this order on the TFT 10, for example. The light-emitting portion 20 is formed on the flattening layer 16, the reflective layer 31, and the reflective layer insulating layer 32. In addition, the TFT 10 is electrically connected to the light-emitting portion 20.

The flattening layer 16 isolates the channel layer 13, the source electrode 14, and the drain electrode 15, for example. An insulating material such as an acrylic resin, a polyimide resin, or the like is used for the flattening layer 16, for example.

The reflective layer 31 reflects light emitted from the light-emitting portion 20. The reflective layer 31 is formed of a metal material such as Al (aluminum), Mg (magnesium), Ag (silver), Cu (copper), or Au (gold). The light reflected by the reflective layer 31 can improve the luminous efficiency of the light-emitting device 1. Of these, Al and Mg are preferable because they have a high reflectivity in the visible light region, and the film thickness of the reflective layer 31 is preferably 10 nm or greater and 1 μm or less. Further, the reflective layer 31 only needs to be formed, for example, in a region other than the region where the TFT 10 is formed, that is, a region where the light-emitting portion 20 is formed, or the like. Note that it can be said that the reflective layer 31 in the present embodiment is provided on a side opposite to the light-emitting layer 22 side with respect to the cathode 21.

The reflective layer insulating layer 32 has a light transmittance and insulates the reflective layer 31. An insulating material such as an acrylic resin or a polyimide resin is used for the reflective layer insulating layer 32, for example.

As illustrated in FIG. 1, the light-emitting portion 20 in the present embodiment includes, for example, a light-emitting layer 22 sandwiched between the cathode 21 and the anode 24. In addition, a hole transport layer 23 is provided between the anode 24 and the light-emitting layer 22.

The cathode 21 supplies electrons to the light-emitting layer Further, the cathode 21 in the present embodiment is made of, for example, an n-type semiconductor (hereinafter, the n-type semiconductor in the cathode 21 is sometimes referred to as a second n-type semiconductor). The cathode 21 preferably has light transmittance. Examples of a material that may serve as this n-type semiconductor include an oxide semiconductor such as indium gallium zinc oxide (IGZO), indium zinc oxide (IZO), gallium-added zinc oxide (GZO), aluminum-added zinc oxide (AZO), ZnO, In₂O₃, and Ga₂O₃. Further, the cathode 21 is electrically connected to the drain electrode 15. Further, the cathode 21 is preferably directly connected to the drain electrode 15. The cathode 21 in the present embodiment is formed of an n-type semiconductor and is directly connected to the light-emitting layer 22, thereby also functioning as a so-called electron injection layer that facilitates injection of electrons into the light-emitting layer 22, and an electron transport layer that transports electrons to the light-emitting layer 22. This eliminates the need to provide the electron injection layer, the electron transport layer, and the like in addition to the cathode 21, a bonding interface between the cathode 21 and the electron injection layer or the like that may become a barrier of electron injection is reduced, and the drive voltage of the light-emitting device 1 is lowered, so that it is possible to achieve a good luminous efficiency. Furthermore, the cathode 21 can be formed using the same equipment as the channel layer 13 in the TFT 10, and the manufacturing process can be simplified, so that it is possible to reduce the manufacturing cost.

A carrier concentration in the first n-type semiconductor (channel layer 13) is preferably greater than a carrier concentration in the second n-type semiconductor (cathode 21). This can improve the transportation efficiency of electrons from the channel layer 13 to the cathode 21. The carrier concentration in the first n-type semiconductor and the carrier concentration in the second n-type semiconductor can be adjusted by changing the concentration of impurities, for example, in a case where the channel layer 13 and the cathode 21 are formed by a sputtering method. Further, the carrier concentration in the channel layer 13 is preferably 10¹⁷ cm⁻³ or less. This makes it possible to more easily adjust the carrier concentration in the cathode 21. Furthermore, the carrier concentration in the cathode 21 is preferably 10¹⁸ cm⁻³ or greater, and the resistivity in the cathode 21 is preferably 10⁻⁴ Ω·cm or less. This makes it possible to obtain sufficient electron transportation even in consideration of a wiring line size from the TFT 10 to the light-emitting device 1 assumed, in particular, in a case where a 60-inch size display device has a 4K resolution.

Further, energy of the valance band maximum (VBM) of the first n-type semiconductor is preferably smaller than energy of the VBM of the second n-type semiconductor. This can improve the transportation efficiency of electrons from the channel layer 13 to the cathode 21.

Furthermore, an absolute value of a difference between energy of the conduction band minimum (CBM) of the first n-type semiconductor and energy of the CBM of the second n-type semiconductor is preferably 0.5 eV or less. This can improve the transportation efficiency of electrons from the channel layer 13 to the cathode 21.

Here, as an example, FIG. 2 shows relationships among the energy of CBM (conduction band minimum), the energy of VBM (valence band maximum), Eg (band gap energy), Ef (Fermi level), n (electron density), μ (electron mobility), ρ (resistivity), and a factor of carrier concentration control in each material of IZO, GZO, AZO, ZnO, In₂O₃, Ga₂O₃, and IGZO. These materials are combined as the first n-type semiconductor and the second n-type semiconductor and subjected to various types of processing to adjust the respective values, so that it is possible to form the light-emitting device 1 according to the present embodiment.

The light-emitting layer 22 emits light using electrons supplied from the cathode 21 and holes supplied from the anode 24. That is., the light-emitting layer 22 is provided between the cathode 21 and the anode 24. The light-emitting layer 22 includes a light-emitting material, for example. Examples of the light-emitting material include organic light-emitting materials and quantum dots. which are semiconductor nanoparticles,

Further, in order to inject electrons from the cathode 21 into the light-emitting layer 22, the CBM of the cathode 21 is preferably deeper than the CBM of the light-emitting layer 22. In addition, the difference between the CBM of the light-emitting layer 22 and the CBM of the cathode 21 is preferably 1.5 eV or less. Furthermore, the Fermi level of the cathode 21 is preferably shallower than the Fermi level of the light-emitting layer 22, and the difference therebetween is preferably large. This makes it possible to improve the transportation efficiency of electrons from the cathode 21 to the light-emitting layer 22.

In addition, in order to confine holes injected from the hole transport layer 23, which is described below, in the light-emitting layer 22, the VBM of the cathode 21 is preferably deeper than the VBM of the light-emitting layer 22. The difference between the VBM of the cathode 21 and the VBM of the light-emitting layer is preferably 1 eV or greater. This makes it possible to efficiently recombine holes and electrons in the light-emitting layer 22, thereby improving the luminous efficiency.

The anode 24 supplies holes to the light-emitting layer 22. Further, the anode 24 is provided so as to face the cathode 21. The anode 24 is made of, for example, a conductive material having conductivity. The anode 24 is preferably transparent. Specific examples of the transparent conductive material include indium tin oxide (ITO), indium zinc oxide (IZO), tin oxide (SnO₂), fluorine-doped tin oxide (IFTO), and the like,

The hole transport layer 23 transports holes from the anode 24 to the light-emitting layer 22. The hole transport layer 23 is preferably transparent. Specific examples of a material used for the hole transport layer 23 include NiO, Cr₂O₃, MgO, LaNiO₃, MoO₃, WO₃, and the like. The hole transport layer 23 may also serve as a hole injection layer that facilitates injection of holes from the anode 24 to the light-emitting layer 22.

Note that the cathode 21, the light-emitting layer 22, and the hole transport layer 23 in the present embodiment are formed in a predetermined pattern, for example, separated into island shapes by a bank 25. For the bank 25, for example, an insulating material such as an acrylic resin or a polyimide resin is used. On the other hand, the anode 24 is, for example, a common electrode formed on the entire surface.

According to the light-emitting device 1 of the present embodiment, a drain of the TFT 10 including the channel layer 13 made of the first n-type semiconductor and the cathode 21 made of the second n-type semiconductor are electrically connected to each other. The cathode 21 is made of the second n-type semiconductor, and thus the cathode 21 functions as both an electron transport layer that transports electrons to the light-emitting layer 22 and as a cathode. As such, as compared with a case where an electron transport layer is separately provided, it is possible to reduce the number of bonding surfaces between layers from the TFT 10 to the light-emitting layer 22 to reduce transportation barriers of electrons at the bonding surfaces, so that a good luminous efficiency in the light-emitting device 1 can be achieved.

Note that the light-emitting device 1 according to the present embodiment has been illustrated as a so-called top-emission type light-emitting device in which light from the light-emitting layer 22 is reflected on the reflective layer 31 to perform display toward the anode side. However, the light-emitting device 1 is not limited to the above configuration, and may have a configuration in which the reflective layer 31 and the reflective layer insulating layer 32 are omitted, or may be a so-called bottom-emission type light-emitting device in which the reflective layer 31 and the reflective layer insulating layer 32 are not provided and the anode 24 is formed of a light reflective material.

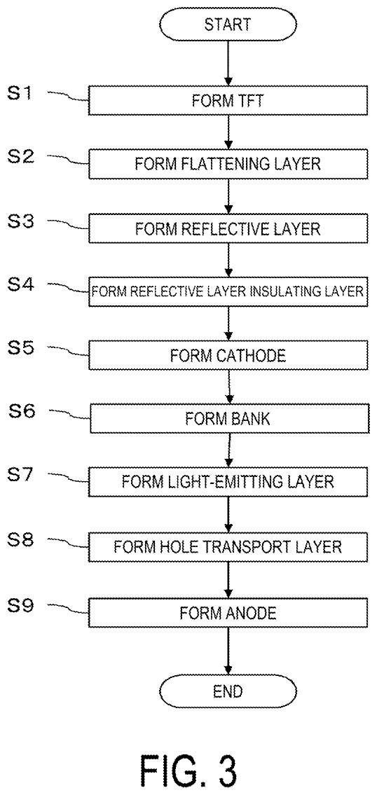

Next, an example of a method for manufacturing the light-emitting device 1 according to the present embodiment will be described with reference to FIGS. 1 and 3.

First, the TFT 10 is formed on the substrate 2 (S1). The method for forming the TFT 10 is not particularly limited, and the TFT 10 can be manufactured by a conventional method, for example.

The flattening layer 16 is formed on the ITT 10 in such a manner that the surface thereof becomes fiat (S2). The flattening layer 16 can be formed by applying, on the TFT 10, a solution in which an insulating material such as polyimide is dissolved, and baking, for example.

The reflective layer 31 is formed on the flattening layer 16 (S3). The reflective layer 31 can be formed by a method such as vapor deposition, for example. Further, before the reflective layer 31 is formed, for example, a first mask covering a portion on the flattening layer 16 is formed, the portion corresponding to the drain electrode 15. Then, the first mask is removed by lift-off or the like to remove the reflective layer of the portion corresponding to the first mask.

The reflective layer insulating layer 32 is formed on the reflective layer 31 (S4). The reflective layer insulating layer 32 can be formed by a method similar to the flattening layer 16, for example. More specifically, for example, a second mask is formed in which a portion on the reflective layer insulating layer 32 is open, the portion corresponding to the drain electrode 15. The opening portion of the second mask also corresponds to the portion where the reflective layer is removed. Then, the reflective layer insulating layer 32 and the flattening layer 16 in the opening portion of the second mask are removed by ashing via the second mask to form a contact hole portion from which the drain electrode 15 is exposed. Thereafter, the second mask is removed. Note that the contact hole portion is formed in such a manner that the reflective layer 31 is not exposed. That is, the reflective layer 31 is isolated and insulated from other layers by the flattening layer 16 and the reflective layer insulating layer 32.

The cathode 21 is formed on the reflective layer insulating layer 32 (S5). The cathode 21 is formed by a sputtering method, for example. The cathode 21 is patterned into a predetermined shape, for example. More specifically, a third mask covering a portion on the reflective layer insulating layer 32, in which a cathode is not formed, is formed to form a layer of a material forming the cathode 21. Then, the third mask is removed and at the same time a portion corresponding to the third mask is removed, thereby forming the cathode 21 having a predetermined shape. Consequently, the cathode 21 and the drain electrode 15 are electrically connected to each other via the contact hole portion. Further, the cathode 21 and the channel layer 13 are also electrically connected to each other via the drain electrode 15.

The bank 25 is formed on the cathode 21 (S6). The bank 25 can be formed by a method similar to that for the flattening layer 16, for example. More specifically, for example, an insulating material is applied on the cathode 21 and baked to form a layer made of the insulating material. Then, a fourth mask in which a portion corresponding to the cathode 21 is open is formed on the layer made of the insulating material. Then, the bank 25 having an opening portion from which the cathode 21 is exposed is formed by ashing via the fourth mask. Thereafter, the fourth mask is removed.

The light-emitting layer 22 is formed on the cathode 21 exposed at the opening portion of the bank 25 (S7). That is, the light-emitting layer 22 patterned into a predetermined shape in line with the opening portion of the bank 25 is formed. The light-emitting layer 22 can be formed by various methods such as vapor deposition of a light-emitting material via a mask and application by ink-jet to the opening portion of the bank 25.

The hole transport layer 24 is formed on the light-emitting layer 22 formed in the opening portion of the bank 25 (S8). That is, the hole transport layer 24 patterned into a predetermined shape in line with the opening portion of the bank 25 is formed. The hole transport layer 24 can be formed by various methods such as vapor deposition of the light-emitting material via the mask and application by ink-jet to the opening portion of the bank 25.

The anode 24 is formed in the bank 25 and the hole transport layer 24 (SO). The anode 24 can be formed by a sputtering method, for example. Note that the anode 24 may be formed on the hole transport layer 24 over the entire surface of the substrate 2, for example.

In addition, after the anode 24 is formed, a sealing layer may be formed to seal the light-emitting device 1.

In this manner, the light-emitting device 1 according to the present embodiment can be manufactured. According to the method described above, after the cathode 21 is formed, the bank 25, the light-emitting layer 22, and the like are formed. In the present embodiment, the cathode 21 is formed of, for example, an oxide semiconductor material, and thus is resistant to the environment during formation of the bank 25, the light-emitting layer 22, and the like. As such, it is possible to suppress deterioration of the luminous efficiency and the like in a case where the cathode 21 is used in the light-emitting device 1. On the other hand, for example, in a case where a metal material such as Mg or Al is used for a cathode, the cathode may deteriorate by oxidation or the like in the environment at the time of forming the bank 25, the light-emitting layer 22, and the like, and the luminous efficiency and the like may deteriorate when the cathode is used in the light-emitting device 1.

### Second Embodiment

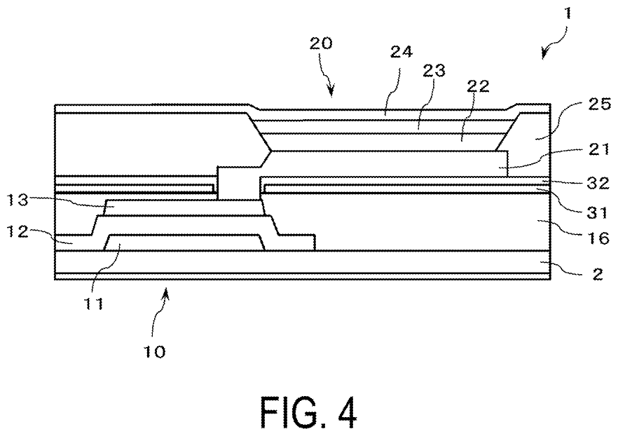

Hereinafter, another embodiment of the disclosure will be described. FIG. 4 is a cross-sectional view schematically illustrating an example of a layered structure of a light-emitting device 1 according to the present embodiment.

In the light-emitting device I of the present embodiment, the drain electrode 15 in the light-emitting device of the first embodiment is not formed. That is, the cathode 21 is directly formed on the channel layer 13. This reduces a process of forming the drain electrode 15 and the like, so that it is possible to manufacture the light-emitting device 1 more efficiently, and reduce manufacturing costs. When the drain electrode 15 is formed, there are two bonding surfaces, that is, a bonding surface between the channel layer 13 and the drain electrode 15 and a bonding surface between the drain electrode 15 and the cathode however, when the cathode 21 is formed directly on the channel layer 13, the number of bonding surfaces can be reduced to one, that is, there is only one bonding surface between the channel layer 13 and the cathode 21, which reduces the transportation barrier of electrons, so that it is possible to make electron transportation from the channel layer 13 to the cathode 21 more efficient.

The present invention is not limited to the embodiments described above, and may be substituted with a configuration that is substantially the same as the configuration described in the embodiments described above, a configuration that achieves the same action and effect, or a configuration capable of achieving the same object.

1. A light-emitting device comprising:
a thin film transistor having a channel layer made of a first n-type semiconductor;
a cathode electrically connected to a drain of the thin film transistor and made of a second n-type semiconductor;
an anode facing the cathode; and
a light-emitting layer provided between the cathode and the anode.

2. The light-emitting device according to claim 1,
wherein a carrier concentration in the first n-type semiconductor is greater than a carrier concentration in the second n-type semiconductor.

3. The light-emitting device according to claim 1,
wherein an energy of a valence band maximum of the first n-type semiconductor is smaller than an energy of a valence band maximum of the second n-type semiconductor.

4. The light-emitting device according to claim 1.
wherein an absolute value of a difference between an energy of a conduction band minimum of the first n-type semiconductor and an energy of a conduction band minimum of the second n-type semiconductor is 0.5 eV or less.

5. The light-emitting device according to claim 1,
wherein the drain and the cathode are directly connected to each other.

6. The light-emitting device according to claim 1,
wherein the cathode and the light-emitting layer are directly connected to each other.

7. The light-emitting device according to claim 1,
wherein the first n-type semiconductor includes at least one selected from IGZO, IZO, GZO, AZO, ZnO, In₂O₃, and Ga₂O₃.

8. The light-emitting device according to claim 1,
wherein the second n-type semiconductor includes at least one selected from IGZO, IZO, GZO, AZO, ZnO, In₂O₃, and Ga₂O₃.

9. The light-emitting device according to claim 1, further comprising:
a reflective layer provided on a side opposite to the light-emitting layer side in the cathode and configured to reflect light emitted from the light-emitting layer.
